(19) United States
(12) Patent Application Publication
(10) Pub. No.: US 2025/0355061 A1
(43) Pub. Date: Nov. 20, 2025

(54) SCOPE OF FAILURE SPECIFYING DEVICE

(71) Applicant: NTT DOCOMO, INC., Tokyo (JP)

(72) Inventors: Tomoki TATSUNO, Chiyoda-ku (JP); Masaki NAKAMURA, Chiyoda-ku (JP); Kazuhiko TAKENO, Chiyoda-ku (JP)

(73) Assignee: NTT DOCOMO, INC., Tokyo (JP)

(21) Appl. No.: 18/869,926

(22) PCT Filed: Mar. 31, 2023
(86) PCT No.: PCT/JP2023/013673

§ 371 Date: Nov. 27, 2024

(30) Foreign Application Priority Data
Jun. 8, 2022 (JP) 2022-093051

(51) Int. Cl. G01R 31/67; H02J 7/35

(52) U.S. Cl. CPC G01R 31/67; H02J 7/35

(57) ABSTRACT

An object is to specify a failure range where a failure occurs in an electrical device. A server 1 includes: a storage unit 10 that stores wiring information regarding a wiring of an electrical device; a failure information acquisition unit 14 that acquires failure information indicating a location in the electrical device where a failure has been predicted or determined; and a failure range specifying unit 15 that specifies a failure range where the failure occurs in the electrical device based on the wiring information and the failure information. The server 1 may further include a capacity calculation unit 17 that calculates an electrical capacity for a configuration of the electrical device excluding the failure range.

### TECHNICAL FIELD

One aspect of the present disclosure relates to a failure range specifying device for specifying a failure range where a failure occurs in an electrical device.

### BACKGROUND ART

The following Patent Literature 1 discloses an estimation device that estimates an electrical device that has failed among a plurality of electrical devices.

### CITATION LIST

### Patent Literature

Patent Literature 1: Japanese Unexamined Patent Publication No. 2018-165635

### SUMMARY OF INVENTION

### Technical Problem

However, it is not possible to specify a failure range where a failure occurs in an electrical device with the estimation device described above. Therefore, it is desirable to specify a failure range where a failure occurs in an electrical device.

### Solution to Problem

A failure range specifying device according to one aspect of the present disclosure includes: a storage unit that stores wiring information regarding wiring of an electrical device; an acquisition unit that acquires failure information indicating a location in the electrical device where a failure has been predicted or determined; and a specifying unit that specifies a failure range where the failure occurs in the electrical device based on the wiring information and the failure information.

In such an aspect, it is possible to specify a failure range where a failure occurs in the electrical device based on the wiring information and the failure information.

### Advantageous Effects of Invention

According to one aspect of the present disclosure, it is possible to specify a failure range where a failure occurs in the electrical device.

### BRIEF DESCRIPTION OF DRAWINGS

FIG. 1 A diagram showing an example of the system configuration of a power system including a failure range specifying device according to an embodiment.

FIG. 2 A diagram showing an example of the system configuration of a conventional DC power supply system.

FIG. 3 A diagram showing an example of the system configuration of a base station.

FIG. 4 A diagram showing an example of the functional configuration of an HEMS included in a base station.

FIG. 5 A flowchart showing an example (storage battery module version) of a process performed by the HEMS included in the base station.

FIG. 6 A flowchart showing an example (solar module version) of a process performed by the HEMS included in the base station.

FIG. 7 A diagram showing an example of the functional configuration of a failure range specifying device according to an embodiment.

FIG. 8 A diagram showing an example of the system configuration of a module.

FIG. 9 A diagram showing an example of a table of wiring information.

FIG. 10 A diagram showing an example of a breaker information table.

FIG. 11 A flowchart showing an example (storage battery module version) of a process performed by the failure range specifying device according to the embodiment.

FIG. 12 A flowchart showing an example (solar module version) of a process performed by the failure range specifying device according to the embodiment.

FIG. 13 A diagram showing an example of the hardware configuration of a computer used in the failure range specifying device according to the embodiment.

### DESCRIPTION OF EMBODIMENTS

Hereinafter, embodiments of the present disclosure will be described in detail with reference to the diagrams. In addition, in the description of the diagrams, the same elements are denoted by the same reference numerals, and repeated description thereof will be omitted. In addition, the embodiments of the present disclosure in the following description are specific examples of the present invention, and the present invention is not limited to these embodiments unless there is a statement that specifically limits the present invention.

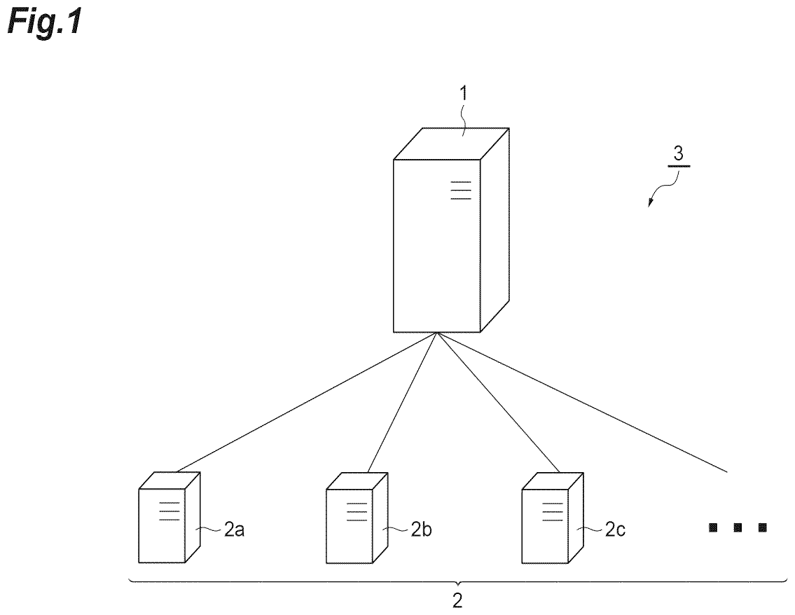

FIG. 1 is a diagram showing an example of the system configuration of a power system 3 including a failure range specifying device (server 1) according to an embodiment. As shown in FIG. 1, the power system 3 includes the server 1 and one or more base stations 2 (hereinafter, the one or more base stations 2 are collectively referred to as “base station 2” as appropriate). The server 1 and each base station 2 are communicatively connected to each other through a communication network, so that information can be transmitted and received therebetween.

The server 1 is a computer device for specifying a failure range where a failure occurs in an electrical device. The electrical device is a device that operates using electricity. The electrical device may be a device that operates when electricity flows through the electrical wiring included in the electrical device. In the present embodiment, explanation will be given using a storage battery or a solar panel provided in the base station 2 as a specific example of the electrical device. However, the electrical device is not limited thereto. For example, the electrical device may be a rectifier. The server 1 coordinates a group of (remote) base stations 2. The server 1 will be described in detail later.

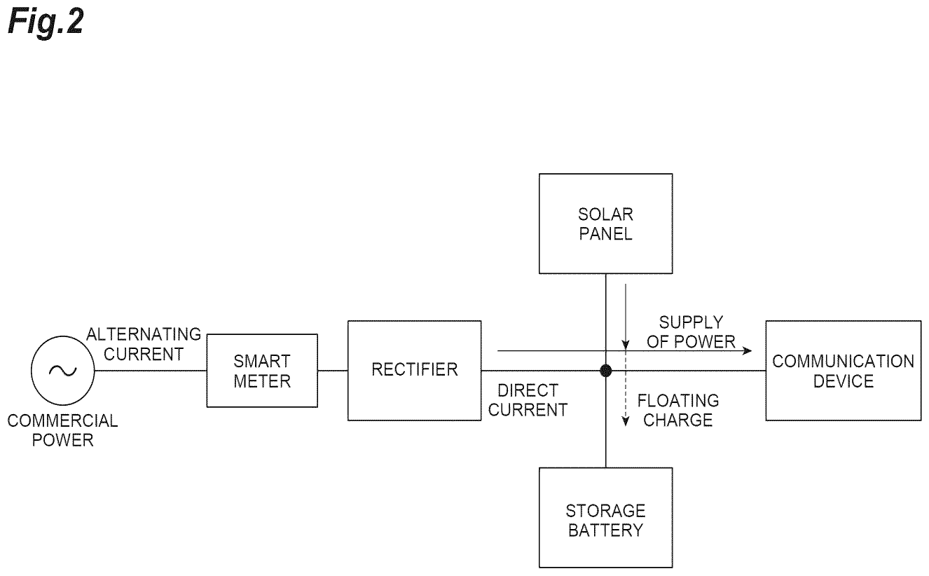

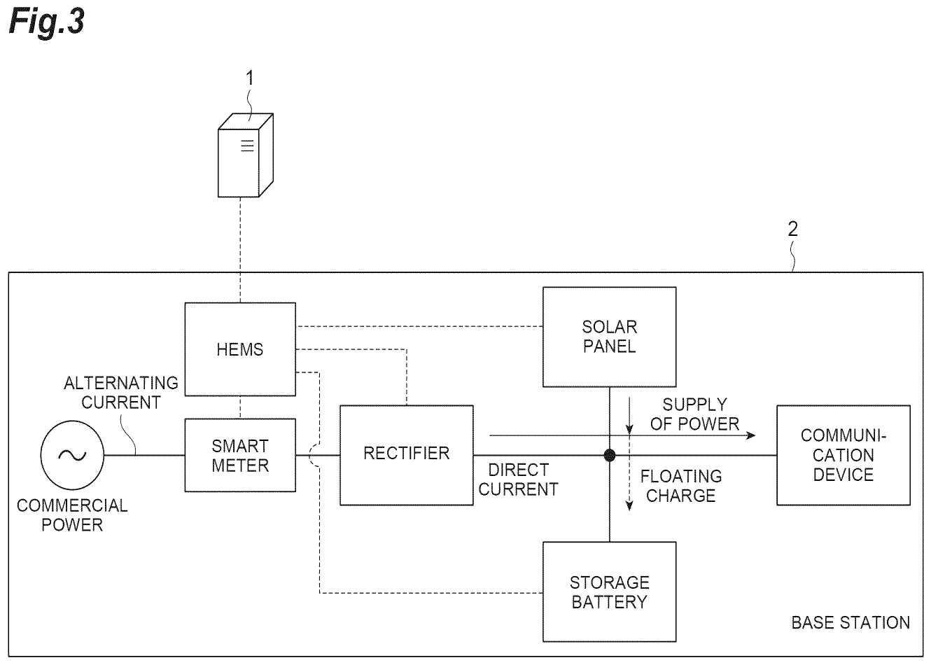

The base station 2 is a wireless base station in a mobile communication system. The base station 2 includes the electrical device described above. The base station 2 is not limited to the wireless base station in the mobile communication network, but may be any computer device including an electrical device. An example of the system configuration of the base station 2 will be described with reference to FIGS. 2 and 3.

FIG. 2 is a diagram showing an example of the system configuration of a conventional DC power supply system. As shown in FIG. 2, the conventional DC power supply system includes a commercial power (commercial power source), a smart meter, a rectifier, a storage battery, a solar panel, and a communication device (load) (which performs communication as a wireless base station). The commercial power and the smart meter are electrically connected to each other and the smart meter and the rectifier are electrically connected to each other, and AC power flows through them. The rectifier converts AC power from commercial power into DC power and outputs it. Any two of the rectifier, the storage battery, the solar panel and the communication device are electrically connected to each other, so that DC power flows therethrough. DC power is supplied to the communication device. By setting the output voltage of the rectifier higher than the voltage of the storage battery, it is possible to supply power to the communication device while performing charging. On the other hand, by setting the output voltage of the rectifier lower than the voltage of the storage battery, it is possible to discharge the power from the storage battery to the communication device. In addition, the load does not have to be a communication device, but may be any device.

In recent years, as the proportion of renewable energy used by power suppliers has increased, solar power generation and storage battery systems have been attracting attention. Since the amount of power generated by renewable energy such as solar power generation and wind power generation increases or decreases depending on the weather (the amount of solar radiation, the amount of wind, and the like), power adjustment that can flexibly respond to such fluctuations is required. As a measure to achieve this, it is common to use battery storage systems together with renewable energy. The range is effective not only for homes but also for wireless base stations.

FIG. 3 is a diagram showing an example of the system configuration of the base station 2. As shown in FIG. 3, the base station 2 includes the system configuration of the conventional DC power supply system shown in FIG. 2. The base station 2 further includes a Home Energy Management System (HEMS). The HEMS is communicatively connected to each of the smart meter, the rectifier, the storage battery, and the solar panel, so that information can be transmitted and received therebetween. In addition, the HEMS of each base station 2 is communicatively connected to the server 1, so that information can be transmitted and received therebetween. For example, when signal is received from the server 1, the HEMS controls the output voltage of the rectifier and transmits B route data of the smart meter to the server 1 together with information of the rectifier, the storage battery, and the solar panel.

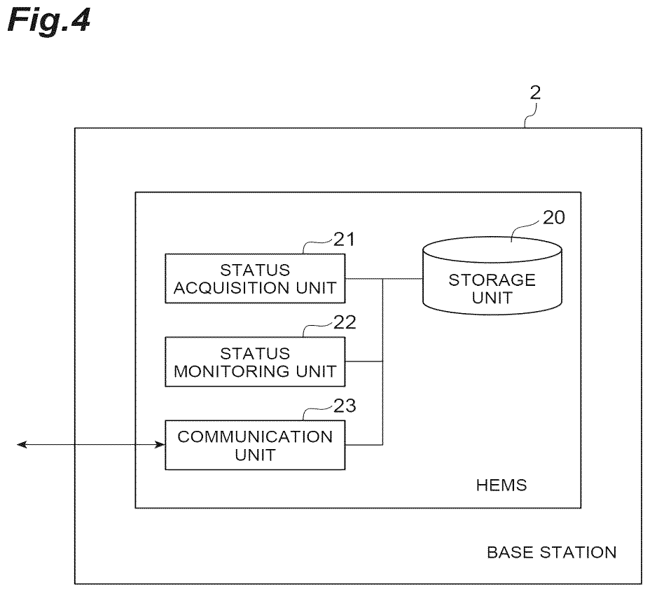

FIG. 4 is a diagram showing an example of the functional configuration of the HEMS included in the base station 2. As shown in FIG. 4, the HEMS includes a storage unit 20, a status acquisition unit 21, a status monitoring unit 22, and a communication unit 23.

Each functional block of the HEMS is assumed to function within the base station 2, but is not limited thereto. For example, some of the functional blocks of the HEMS may function within a computer device (for example, the server 1), which is a computer device different from the base station 2 and is connected to the base station 2 through a network, while appropriately transmitting and receiving information to and from the base station 2. In addition, some of the functional blocks of the HEMS may be omitted, a plurality of functional blocks may be integrated into one functional block, or one functional block may be separated into a plurality of functional blocks.

Hereinafter, each function of the HEMS shown in FIG. 4 will be described.

The storage unit 20 may store any information used in calculations in the HEMS, results of the calculations in the HEMS, and the like. The information stored in the storage unit 20 may be referred to as appropriate by each function of the HEMS.

The status acquisition unit 21 acquires status information regarding the status of the storage battery and the solar panel, which are electrical devices provided in the base station 2. The status information is, for example, at least one of the output power, power storage capacity, current, voltage and temperature of the storage battery (or a storage battery module forming the storage battery) and the output power, power generation capacity, current (input current, output current), voltage (input voltage, output voltage), and temperature of the solar panel (or a solar module forming the solar panel). The status information may be associated with time information regarding the time when the status information is acquired, electrical device information for identifying the electrical device whose status information has been acquired, and the like. For example, the status acquisition unit 21 acquires status information from an existing sensor device provided in the electrical device. The sensor device is, for example, a temperature sensor and a current and voltage sensor. When the solar panel does not originally have a temperature sensor, a temperature sensor (thermometer) may be installed at the panel installation site. The sensor device may be provided inside the electrical device. The status acquisition unit 21 may acquire the status information directly from the electrical device, rather than through the sensor device. The status acquisition unit 21 may acquire the status information periodically (for example, once every 10 seconds), or may acquire the status information according to the schedule set in advance. The status acquisition unit 21 may store the acquired status information in the storage unit 20, or may output the acquired status information to the communication unit 23.

The status monitoring unit 22 checks the device status (failure status) of the storage battery and the solar panel, which are electrical devices provided in the base station 2, and generates device status information that is the result of the check. More specifically, first, the status monitoring unit 22 acquires, from an existing monitoring unit provided in the base station 2, information indicating whether the electrical device is currently operating normally or operating abnormal (unable to operate normally). The monitoring unit is, for example, a communication device that monitors the status of each device in the base station 2. Then, based on the acquired information, the status monitoring unit 22 checks whether the electrical device is operating normally or operating abnormally (whether or not a failure is currently occurring). Then, as a result of the check, the status monitoring unit 22 generates device status information indicating whether the electrical device is operating normally or operating abnormally. When the device status information indicates that the electrical device is operating abnormally, the device status information includes failure information indicating a part of the electrical device determined to be abnormal (that is, has failed) by the monitoring unit described above (for example, information for identifying a module determined to have failed). The device status information may be associated with time information regarding the time when the device status information is acquired, electrical device information for identifying the electrical device whose device status information has been acquired, and the like. The status monitoring unit 22 may generate the device status information periodically (for example, once every 10 seconds), or may generate the device status information according to the schedule set in advance. The status monitoring unit 22 may store the acquired device status information in the storage unit 20, or may output the acquired device status information to the communication unit 23.

The communication unit 23 transmits, to the server 1 (its communication unit 11), status data including at least one of the status information stored in the storage unit 20 or input from the status acquisition unit 21 and the device status information stored in the storage unit 20 or input from the status monitoring unit 22. The communication unit 23 may transmit the status data periodically (for example, once every 10 seconds), may transmit the status data according to the schedule set in advance, or may transmit the status data when predetermined criteria are met (for example, when the data capacity of the status data reaches a predetermined capacity).

The communication unit 23 may perform other general communications. For example, any data may be transmitted to the server 1, any instruction may be transmitted to the server 1, any data may be received from the server 1, or any instruction may be received from the server 1 and processing may be performed according to the instruction.

In the present embodiment as a whole, how to perform various processes on a specific electrical device is described. The specific electrical device is identified based on, for example, the electrical device information described above. In order to target a specific electrical device, electrical device information is associated with various kinds of information or electrical device information is matched in various processes. However, the description thereof will be omitted for the sake of simplicity.

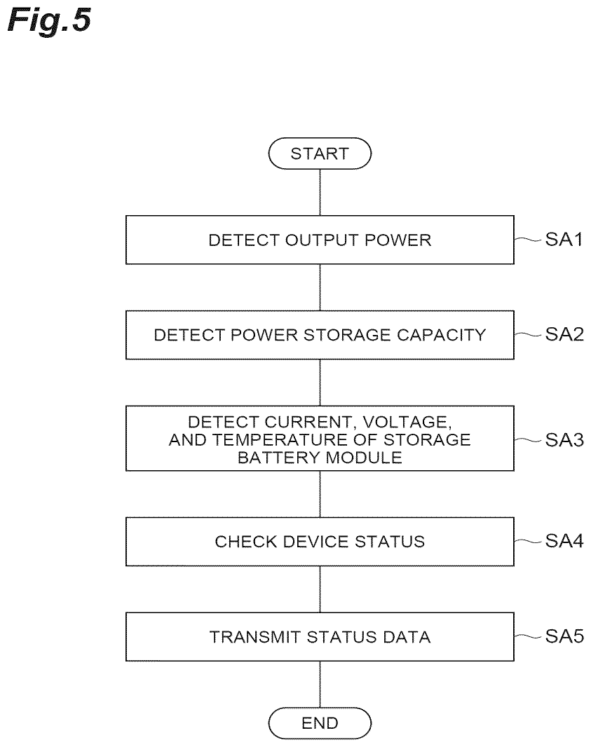

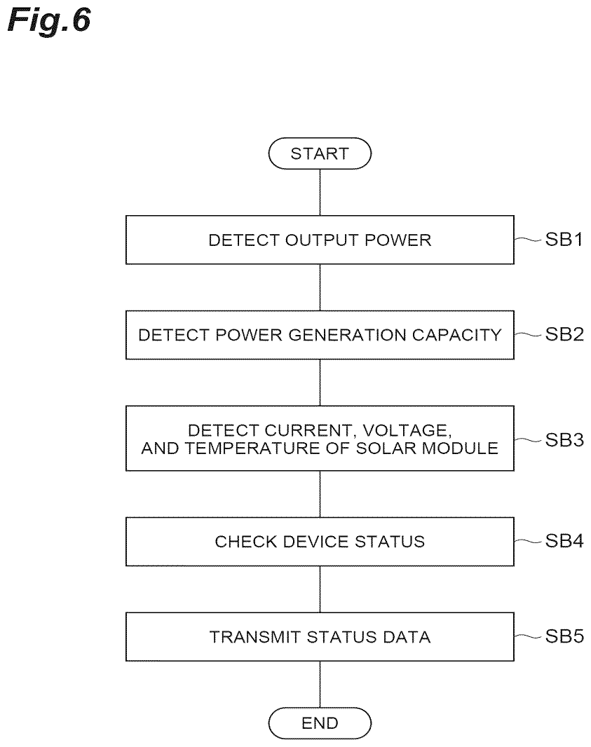

Next, an example of processing performed by the HEMS included in the base station 2 will be described with reference to FIGS. 5 and 6.

FIG. 5 is a flowchart showing an example (storage battery module version) of a process performed by the HEMS included in the base station 2. This is a process when it is assumed that the base station 2 includes a storage battery configured by a storage battery module as an electrical device. First, the status acquisition unit 21 detects the output power of the storage battery and acquires this as status information (step SA1). Then, the status acquisition unit 21 detects the power storage capacity of the storage battery and acquires this as status information (step SA2). Then, the status acquisition unit 21 detects the current, voltage, and temperature of the storage battery module and acquires these as status information (step SA3). Then, the status monitoring unit 22 checks the device status of the storage battery to generate device status information (step SA4). Then, the communication unit 23 transmits status data including the status information acquired in SA1, SA2, and SA3 and the device status information generated in SA4 to the server 1 (step SA5). In addition, the processes of SA1 to SA4 may be performed in any order before the process of SA5, and may be performed multiple times.

FIG. 6 is a flowchart showing an example (solar module version) of a process performed by the HEMS included in the base station 2. This is a process when it is assumed that the base station 2 includes a solar panel configured by a solar module as an electrical device. First, the status acquisition unit 21 detects the output power of the solar panel and acquires this as status information (step SB1). Then, the status acquisition unit 21 detects the power generation capacity of the solar panel and acquires this as status information (step SB2). Then, the status acquisition unit 21 detects the current, voltage, and temperature of the solar module and acquires these as status information (step SB3). Then, the status monitoring unit 22 checks the device status of the solar panel to generate device status information (step SB4). Then, the communication unit 23 transmits status data including the status information acquired in SB1, SB2, and SB3 and the device status information generated in SB4 to the server 1 (step SB5). In addition, the processes of SB1 to SB4 may be performed in any order before the process of SB5, and may be performed multiple times.

Next, the server 1 will be described in detail.

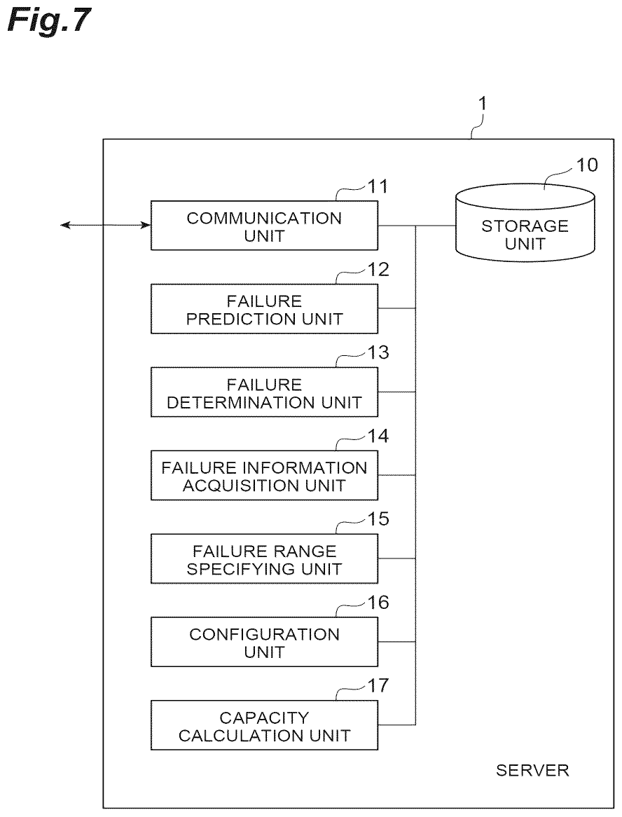

FIG. 7 is a diagram showing an example of the functional configuration of the failure range specifying device (server 1) according to the embodiment. As shown in FIG. 7, the server 1 includes a storage unit 10 (storage unit), a communication unit 11, a failure prediction unit 12, a failure determination unit 13, a failure information acquisition unit 14 (acquisition unit), a failure range specifying unit 15 (specifying unit), a configuration unit 16 (configuration unit), and a capacity calculation unit 17 (calculation unit).

Each functional block of the server 1 is assumed to function within the server 1, but is not limited thereto. For example, some of the functional blocks of the server 1 may function within a computer device (for example, the base station 2), which is a computer device different from the server 1 and is connected to the server 1 through a network, while appropriately transmitting and receiving information to and from the server 1. In addition, some of the functional blocks of the server 1 may be omitted, a plurality of functional blocks may be integrated into one functional block, or one functional block may be separated into a plurality of functional blocks.

Hereinafter, each function of the server 1 shown in FIG. 7 will be described.

The storage unit 10 stores wiring information regarding the wiring of the electrical device. The storage unit 10 may store any other information used in the calculations and the like in the server 1, results of the calculations in the server 1, and the like. The information stored in the storage unit 10 may be referred to as appropriate by each function of the server 1.

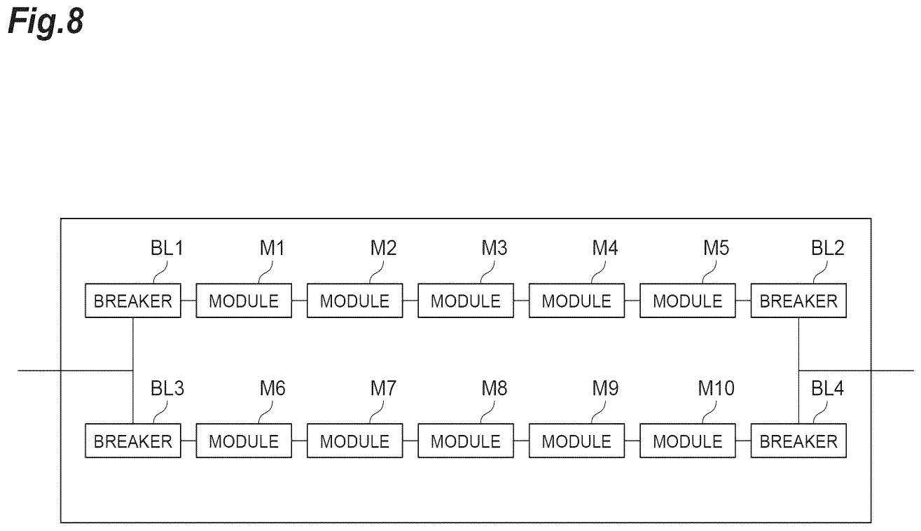

The wiring information will be described with reference to FIGS. 8 to 10.

FIG. 8 is a diagram showing an example of the system configuration of a module. The module may be a storage battery module or a solar module. The module shown in FIG. 8 will be described assuming that the module is a storage battery module provided in the base station 2. However, the “storage battery module” may be read as a “solar module” as appropriate hereinbelow. In the storage battery module shown in FIG. 8, ten storage battery modules M1 to M10 are mounted. That is, a plurality of (ten) storage battery modules are combined in the storage battery. In addition, the storage battery modules M1, M2, M3, M4, and M5 are connected in series to form an assembly (unit). Similarly, the storage battery modules M6, M7, M8, M9, and M10 are connected in series to form a unit. That is, the storage battery has two units each of which includes five modules connected in series to each other. In addition, the number of units may differ for each electrical device or for each base station 2. Therefore, the storage battery capacity (or power generation capacity) may be different for each electrical device or for each base station 2. Breakers BL1 to BL4 will be described later.

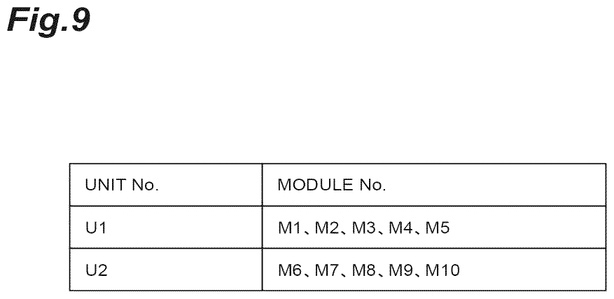

FIG. 9 is a diagram showing an example of a table of wiring information. More specifically, FIG. 9 is a diagram showing an example of a table of wiring information of the module shown in FIG. 8. As shown in FIG. 9, in the wiring information, “unit No.” for identifying a unit and “module No.” for identifying a storage battery module, which is a component of the unit, are associated with each other. The wiring information shown in FIG. 9 indicates that five storage battery modules having module No. M1, M2, M3, M4, and M5 form a unit having unit No. U1 (unit U1) and five storage battery modules having module No. M6, M7, M8, M9, and M10 form a unit having unit No. U2 (unit U2).

Returning to FIG. 8, the breaker BL1 is connected to one end of the unit U1 formed by M1, M2, M3, M4, and M5, and the breaker BL2 is connected to the other end. Similarly, the breaker BL3 is connected to one end of the unit U2 formed by M6, M7, M8, M9, and M10, and the breaker BL4 is connected to the other end. By operating the breakers on both ends of the unit, the supply of power to the unit can be controlled. That is, any unit can be (electrically) disconnected. The server 1 manages breaker information regarding breakers.

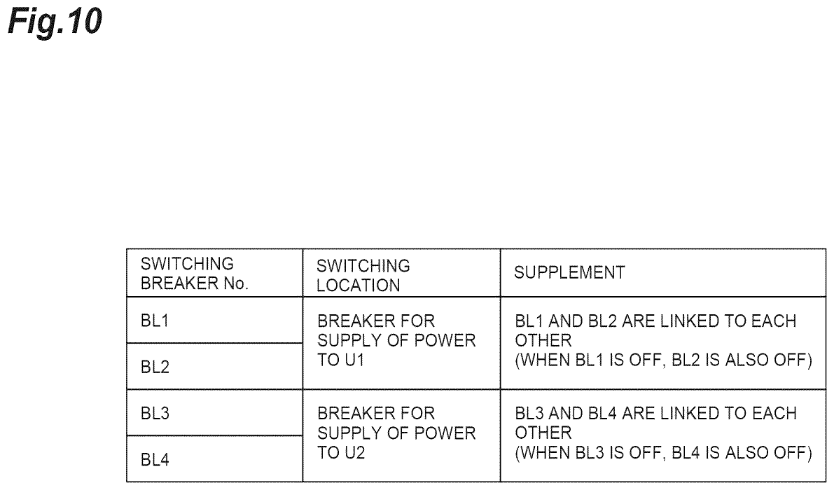

FIG. 10 is a diagram showing an example of a table of breaker information. More specifically, FIG. 10 is a diagram showing an example of a table of breaker information of the module shown in FIG. 8. As shown in FIG. 10, in the breaker information, “switching breaker No.” for identifying a breaker, “switching location” indicating a unit for which the breaker (or breakers) is switched, and supplementary description of the breaker (or breakers) are associated with each other. The breaker information shown in FIG. 10 indicates that two breakers (the breaker BL1 and the breaker BL2) having switching breaker numbers BL1 and BL2 are breakers for the supply of power to the unit U1 and the breaker BL1 and the breaker BL2 are linked to each other (when the breaker BL1 is OFF (no power is supplied), the breaker BL2 is also OFF, and when the breaker BL1 is ON (power is supplied), the breaker BL2 is also ON). Similarly, the breaker information shown in FIG. 10 indicates that the breaker BL3 and the breaker BL4 are breakers for the supply of power to the unit U2 and the breaker BL3 and the breaker BL4 are linked to each other.

The communication unit 11 receives status data (including status information and device status information) transmitted from the base station 2 (its communication unit 23). The communication unit 11 stores the received status data in the storage unit 10.

Based on the received status data (or the status data stored in the storage unit 10), the communication unit 11 detects whether or not a failure is currently occurring in the electrical device of the base station 2. More specifically, when the device status information included in the received status data indicates that the electrical device is operating normally, the communication unit 11 detects that no failure is currently occurring, and when the device status information indicates that the electrical device is operating abnormally, the communication unit 11 detects that a failure is currently occurring. When it is detected that a failure is currently occurring in the electrical device, the communication unit 11 outputs a failure determination instruction to the failure determination unit 13 to determine a failure. The failure determination instruction includes the failure information included in the device status information. On the other hand, when it is detected that no failure is currently occurring in the electrical device, the communication unit 11 outputs a failure prediction instruction to the failure prediction unit 12 to predict a failure. That is, the communication unit 11 determines the necessity of failure prediction based on the device status information.

The communication unit 11 may perform other general communications. For example, any data may be transmitted to the base station 2, any instruction may be transmitted to the base station 2, any data may be received from the base station 2, or any instruction may be received from the base station 2 and processing may be performed according to the instruction.

The failure prediction unit 12 performs a failure prediction analysis on the electrical device included in the base station 2. More specifically, when a failure prediction instruction is input from the communication unit 11, the failure prediction unit 12 performs a failure prediction analysis based on the status information stored in the storage unit 10.

The failure prediction unit 12 predicts a failure of the electrical device based on the data (status information) acquired from the electrical device. Failure prediction includes prediction of the location of failure as well as whether or not a failure has occurred. For example, the failure prediction unit 12 predicts a failure of the storage battery by using the current capacity, current, voltage, and temperature data of the storage battery. In addition, for example, the failure prediction unit 12 predicts a failure of the solar panel by using the output current, output voltage, and temperature data of the solar panel. More specifically, the failure prediction unit 12 compares the prediction of failures due to device-specific deterioration, damage due to external factors, and the like with a huge amount of past device data using data (status information) of each electrical device accumulated in the storage unit 10, and detects an outstanding parameter emitted from the device, which may cause a failure, as a failure prediction.

A method using machine learning or deep learning, such as a kNN (K-nearest Neighbor Algorithm) or an autoencoder, may be used as a technique for predicting the failure of a storage battery using the failure prediction unit 12. Machine learning is a method of predicting the future by deriving trends hidden in a large amount of data by learning and inputting new data for the obtained learning results. Specifically, a model to detect failures in advance from the voltage, current, temperature data, and the like of the storage battery is constructed to make predictions.

A method using machine learning or deep learning, such as a kNN or an autoencoder, may be used as a technique for predicting the failure of a solar panel using the failure prediction unit 12. Specifically, a model to detect failures in advance from the input voltage, current, temperature data, and the like of the solar panel is constructed to make predictions.

When the failure of the electrical device is predicted as a result of the failure prediction analysis (failure prediction detection), the failure prediction unit 12 outputs a failure determination instruction to the failure determination unit 13 to give an instruction to determine the failure. The failure determination instruction includes failure information indicating a location in the electrical device where a failure has been predicted by the failure prediction unit 12 (for example, information for identifying a module for which a failure has been predicted). On the other hand, when no failure of the electrical device is predicted, the failure prediction unit 12 outputs a capacity calculation instruction to the capacity calculation unit 17 to give an instruction to calculate the capacity of the electrical device.

The failure determination unit 13 determines a failure in the electrical device provided in the base station 2. More specifically, when a failure determination instruction is input from the communication unit 11 or the failure prediction unit 12, the failure determination unit 13 determines that the electrical device has failed and outputs failure information included in the failure determination instruction to the failure information acquisition unit 14. In addition, the storage unit 10 may improve the accuracy of the failure prediction analysis by storing (accumulating) status data when a failure of the electrical device is predicted or determined and using the status data when the failure prediction unit 12 performs a failure prediction analysis.

The failure information acquisition unit 14 acquires failure information indicating a location in the electrical device where a failure has been predicted or determined. When a failure of the electrical device is predicted or determined, the failure information acquisition unit 14 may acquire failure information indicating a location in the electrical device where the failure has been predicted or determined. More specifically, the failure information acquisition unit 14 acquires failure information from the failure determination unit 13 when a failure of the electrical device is predicted by the failure prediction unit 12 or when a failure of the electrical device is determined by the status monitoring unit 22, the failure determination unit 13, and the like. The failure information acquisition unit 14 outputs the acquired failure information to the failure range specifying unit 15.

The failure range specifying unit 15 specifies a failure range where the failure has occurred in the electrical device based on the wiring information and the failure information. More specifically, the failure range specifying unit 15 specifies the failure range where the failure has occurred in the electrical device, based on the wiring information stored in the storage unit 10 and the failure information acquired (input) by the failure information acquisition unit 14. The failure range specifying unit 15 outputs failure range information indicating the identified failure range to the configuration unit 16 and the capacity calculation unit 17.

For example, to explain using the module shown in FIG. 8 and the wiring information shown in FIG. 9, when failure information indicates the storage battery module M1 as a location where a failure has been predicted or determined, the failure range specifying unit 15 specifies the unit U1 including the storage battery module M1 (unit to which the storage battery module M1 is connected in series) as a failure range with reference to the wiring information.

The configuration unit 16 causes (reconfigures) the electrical device to have a configuration excluding the failure range (failure-range-excluded configuration). More specifically, when the failure range information is received from the failure range specifying unit 15, the configuration unit 16 configures the electrical device to exclude the failure range indicated by the failure range information. To explain using the above example, the configuration unit 16 removes the unit U1 (storage battery modules M1 to M5) specified as a failure range from the module shown in FIG. 8 (disconnects the whole unit U1), thereby obtaining a configuration including only the unit U2 (storage battery modules M6 to M10). At this time, the configuration unit 16 turns off the breakers BL1 and BL2 with reference to the breaker information shown in FIG. 10 to disconnect the unit U1. When such a configuration is made by the configuration unit 16, the configuration unit 16 outputs information indicating that the configuration has been made to the capacity calculation unit 17.

The capacity calculation unit 17 calculates (recalculates) the electrical capacity for the configuration excluding the failure range of the electrical device. More specifically, when the failure range information is input from the failure range specifying unit 15, the capacity calculation unit 17 calculates the electrical capacity for the configuration of the electrical device excluding the failure range indicated by the failure range information. The electrical capacity may be, for example, a power storage capacity when the electrical device is a storage battery, or may be a power generation capacity when the electrical device is a solar panel. A method for calculating the electrical capacity from the (partial) configuration of the electrical device may be based on the existing techniques. For example, capacity information regarding the electrical capacity of each component of the electrical device may be stored in advance in the storage unit 10, and the capacity calculation unit 17 may perform a calculation based on the capacity information stored in the storage unit 10.

The capacity calculation unit 17 may calculate (recalculate) the electrical capacity for the failure-range-excluded configuration. More specifically, when information indicating that the configuration has been made is input from the configuration unit 16, the capacity calculation unit 17 may calculate the electrical capacity for the failure-range-excluded configuration configured by the configuration unit 16.

To explain using the above example, the capacity calculation unit 17 calculates the electrical capacity (the total capacity of the remaining unit U2) for a configuration including only the unit U2 (storage battery modules M6 to M10) after removing the unit U1 (storage battery modules M1 to M5) specified as a failure range from the module shown in FIG. 8.

When a capacity calculation instruction is input from the failure prediction unit 12, the capacity calculation unit 17 may calculate (recalculate) the electrical capacity for the current configuration of the electrical devices.

The capacity calculation unit 17 may check the wiring information of the base station 2. More specifically, the capacity calculation unit 17 may check the status data (device status information) of the base station 2 for the electrical device reconfigured by the configuration unit 16 and give an instruction to update the settings of the base station 2 through the communication unit 11 if necessary. For example, when the capacity is reduced due to the reconfiguration, if the status monitoring unit 22 continues monitoring the capacity (checking the device status) before the reconfiguration, it is abnormally determined that the capacity has been reduced. For this reason, the capacity calculation unit 17 updates a maximum capacity setting.

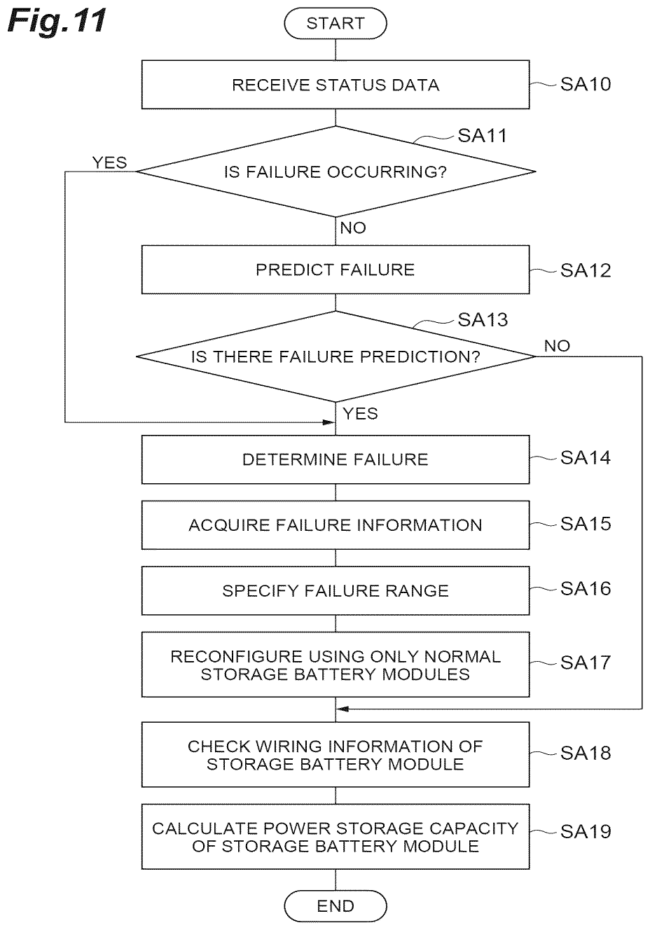

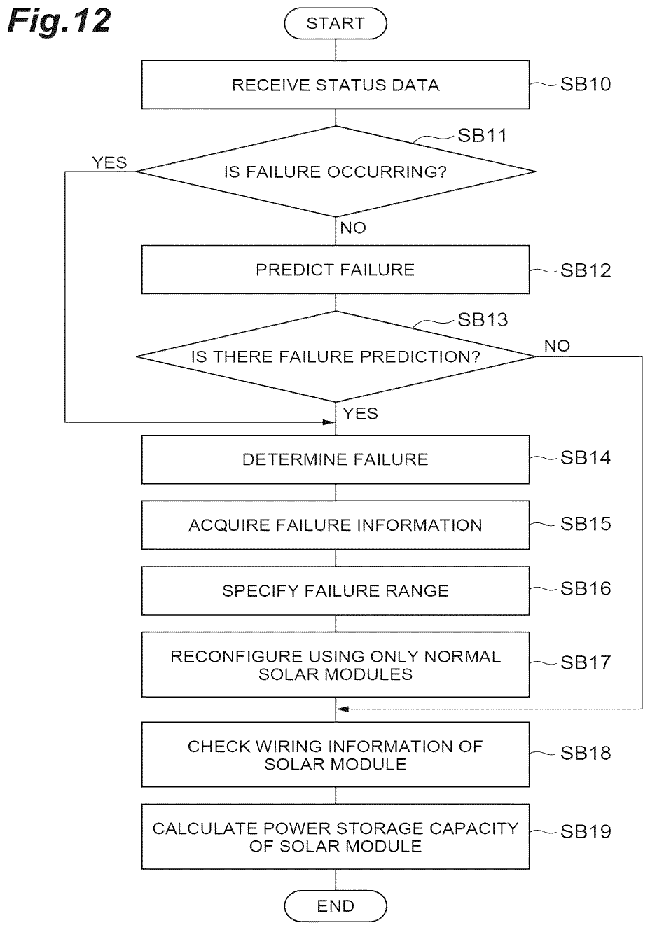

Next, an example of processing performed by the server 1 will be described with reference to FIGS. 11 and 12.

FIG. 11 is a flowchart showing an example (storage battery module version) of a process performed by the failure range specifying device (server 1) according to the embodiment. This is a process when it is assumed that the base station 2 includes a storage battery configured by a storage battery module as an electrical device. First, the communication unit 11 receives status data transmitted from the base station 2 (step SA10). Then, the communication unit 11 detects whether or not a failure is currently occurring in the storage battery provided in the base station 2, based on device status information included in the status data received in SA10 (step SA11). When it is detected that no failure is currently occurring in SA11 (SA11: No), the failure prediction unit 12 performs a failure prediction analysis on the storage battery provided in the base station 2 based on the status information included in the status data received in SA10 (step SA12), and determines whether or not there is a failure prediction (step SA13).

When it is detected that a failure is currently occurring in SA11 (SA11: Yes) or when it is determined that there is a failure prediction in SA13 (SA13: Yes), the failure determination unit 13 determines that the storage battery provided in the base station 2 has failed (step SA14). Then, the failure information acquisition unit 14 acquires failure information indicating a location (storage battery module) in the storage battery provided in the base station 2 where the failure has been predicted or determined (step SA15). The failure information is included in the status data received in SA10 or is generated by the failure prediction unit 12 in SA12. Then, the failure range specifying unit 15 specifies a failure range (storage battery module) where the failure has occurred in the storage battery provided in the base station 2, based on the wiring information stored in the storage unit 10 and the failure information acquired in SA15 (step SA16). Then, the configuration unit 16 configures the storage battery provided in the base station 2 to exclude the failure range (failure-range-excluded configuration) (step SA17). That is, the storage battery is reconfigured using only normal storage battery modules.

When it is determined that there is no failure prediction in SA13 (SA13: No) or subsequent to SA17, the capacity calculation unit 17 checks the wiring information of the storage battery provided in the base station 2 (step SA18). Then, the capacity calculation unit 17 calculates a power storage capacity for the failure-range-excluded configuration of the storage battery provided in the base station 2, which has been reconfigured in SA17 (step SA19). In addition, SA17 and SA18 may be omitted, so that the capacity calculation unit 17 calculates the power storage capacity of the storage battery provided in the base station 2, for the configuration excluding the failure range specified in SA16, subsequent to SA16.

FIG. 12 is a flowchart showing an example (solar module version) of a process performed by the server 1 according to the embodiment. This is a process when it is assumed that the base station 2 includes a solar panel configured by a solar module as an electrical device. First, the communication unit 11 receives status data transmitted from the base station 2 (step SB10). Then, the communication unit 11 detects whether or not a failure is currently occurring in the solar panel provided in the base station 2, based on device status information included in the status data received at SB10 (step SB11). When it is detected that no failure is currently occurring in SB11 (SB11: No), the failure prediction unit 12 performs a failure prediction analysis on the solar panel provided in the base station 2 based on the status information included in the status data received in SB10 (step SB12), and determines whether or not there is a failure prediction (step SB13).

When it is detected that a failure is currently occurring in SB11 (SB11: Yes) or when it is determined that there is a failure prediction in SB13 (SB13: Yes), the failure determination unit 13 determines that the solar panel provided in the base station 2 has failed (step SB14). Then, the failure information acquisition unit 14 acquires failure information indicating a location (solar module) in the solar panel provided in the base station 2 where a failure has been predicted or determined (step SB15). The failure information is included in the status data received in SB10 or is generated by the failure prediction unit 12 in SB12.

Then, the failure range specifying unit 15 specifies a failure range (solar module) where the failure has occurred in the solar panel provided in the base station 2, based on the wiring information stored in the storage unit 10 and the failure information acquired in SB15 (step SB16). Then, the configuration unit 16 configures the solar panel provided in the base station 2 to exclude the failure range (failure-range-excluded configuration) (step SB17). That is, the solar panel is reconfigured using only normal solar modules.

When it is determined that there is no failure prediction in SB13 (SB13: No) or subsequent to SB17, the capacity calculation unit 17 checks the wiring information of the solar panel provided in the base station 2 (step SB18). Then, the capacity calculation unit 17 calculates a power generation capacity for the failure-range-excluded configuration of the solar panel provided in the base station 2, which has been reconfigured in SB17 (step SB19). In addition, SB17 and SB18 may be omitted, so that the capacity calculation unit 17 calculates the power storage capacity of the solar panel provided in the base station 2, for the configuration excluding the failure range specified in SB16, subsequent to SB16.

Next, the function and effect of the server 1 according to the embodiment will be described.

According to the server 1, the storage unit 10 stores wiring information regarding the wiring of the electrical device, the failure information acquisition unit 14 acquires failure information indicating a location in the electrical device where a failure has been predicted or determined, and the failure range specifying unit 15 specifies a failure range where the failure occurs in the electrical device based on the wiring information stored in the storage unit 10 and the failure information acquired by the failure information acquisition unit 14. With this configuration, it is possible to specify the failure range where the failure occurs in the electrical device based on the wiring information and the failure information.

In addition, the server 1 may further include the capacity calculation unit 17 that calculates the electrical capacity for a configuration of the electrical device excluding the failure range. With this configuration, it is possible to calculate the electrical capacity of normal components of the electrical device. Therefore, it is possible to operate the electrical device in consideration of the extent of the impact of the failure.

The server 1 may further include a configuration unit 16 that configures the electrical device to exclude the failure range (failure-range-excluded configuration). With this configuration, it is possible to protect the disconnected electrical device (components in the failure range) and to protect the remaining devices (normal components). That is, it is possible to prevent adverse effects on the remaining devices by quickly excluding a device from the system after the device is determined to have failed. For example, if a serious electrical failure causes a module to short circuit (or may cause a short circuit), it may be too late to take action after the failure has occurred. However, if the failure can be predicted using accumulated data, it is possible to protect the suspected failure module and other modules.

In addition, the server 1 may further include the capacity calculation unit 17 that calculates the electrical capacity for the failure-range-excluded configuration. With this configuration, it is possible to calculate the electrical capacity of the failure-range-excluded configuration (normal components) of the electrical device. Therefore, it is possible to operate the electrical device in consideration of the extent of the impact of the failure.

In addition, in the server 1, when the failure in the electrical device is predicted or determined, the failure information acquisition unit 14 may acquire the failure information indicating a location in the electrical device where the failure has been predicted or determined. With this configuration, when a failure in the electrical device is predicted or determined, it is possible to quickly operate the electrical device in consideration of the extent of the impact of the failure.

In addition, in the server 1, the electrical device may be a storage battery, and the capacity may be a power storage capacity. With this configuration, it is possible to calculate the power storage capacity for the configuration of the storage battery excluding the failure range where the failure occurs.

In addition, in the server 1, the electrical device may be a solar panel, and the capacity may be a power generation capacity. With this configuration, it is possible to calculate the power generation capacity for the configuration of the solar panel excluding the failure range where the failure occurs.

The process performed by the server 1 is a failure prediction method in the storage battery system and the solar power generation system provided in the base station 2. The process performed by the server 1 (or the power system 3) is related to the power generation and storage devices of the wireless base station.

Generally, in a wireless base station, in addition to wireless devices, there are devices that supply power to the wireless devices. Representative examples include a rectifier, a storage battery, and a solar power generation system. In conventional failure detection, these devices are monitored at a remote location, alarms issued by the devices are detected, and then a failure response is performed according to the contents. On the other hand, a problem with the conventional monitoring method is that it takes time to prepare a substitute device between the occurrence of a failure and the replacement of the device. In addition, in order to predict the occurrence of a failure, it is necessary to detect abnormal noises or to install a surveillance camera to detect whether or not there is an abnormality in the appearance, but this requires the installation of a new device. As a result, additional costs are required.

The process performed by the server 1 (or the power system 3) is a device failure prediction method in which existing monitoring units and sensor devices are used and which does not require the installation of a new device. According to the server 1 (or the power system 3), it is possible to prevent the occurrence of failures in the solar power generation system or the storage battery provided in the base station 2, and it is possible to shorten the time from the actual occurrence of a failure to recovery by preparing substitute devices for these devices in advance. In addition, failure prediction using the output data from the device makes it possible to reduce the introduction costs without the need to install a new device.

In the server 1, when a failure is predicted or determined as a current status by the failure prediction unit 12 or the failure determination unit 13, the corresponding device of the base station 2 may be replaced with a substitute device. In addition, in the server 1, when an unexpected event occurs in a power supply device that is expected to fail based on a failure or failure prediction, power may be supplied to the wireless device in advance using a normal module. This makes it possible to optimize power supply resources at the module level even in a situation where a failure is known, from the perspective of continuing the supply of power to the base station device. Generally, the range of a failure is limited in many systems, and the server 1 has a function of specifying the failure range in consideration of the wiring in the case of a failure in the storage battery or the solar panel.

According to the server 1, in the storage battery or the solar power generation system, optimization is performed by removing the analysis results of failure determination or failure prediction from the connection information of the storage battery or the solar power generation module. Therefore, it is possible to operate the device in consideration of the extent of the impact of the failure based on the condition of the device while waiting for replacement.

The server 1 takes into consideration the different wiring information (storage battery or solar panel configuration information) of each base station 2 in addition to the failure prediction analysis on each storage battery or solar panel module. In the server 1, it is considered that units connected in series to each other will be reconfigured by predicting a failure in a single module. Therefore, it is possible to estimate the remaining battery capacity in consideration of the worst case such as a disaster (such as a secondary disaster due to failure). In addition, as a secondary disaster, there is a possibility that a normal storage battery or solar panel in a series connection state may be affected by a storage battery or a solar panel, which has failed, to lower the performance.

The server 1 predicts (recalculates) the power storage capacity, the power generation capacity, and the like according to failure prediction.

The power system 3 may have the following configuration.

### [Item 1]

A DC power supply system including a storage battery and a solar power generation, wherein a failure in the storage battery or the solar power generation is predicted based on data acquired from the storage battery or the solar power generation.

### [Item 2]

The DC power supply system according to item 1, wherein a failure in the storage battery is predicted by using the current capacity, current, voltage, and temperature data of the storage battery.

### [Item 3]

The DC power supply system according to item 1, wherein a failure in the solar power generation is predicted by using the output current, output voltage, and temperature data of the solar power generation.

### [Item 4]

The DC power supply system according to item 1, wherein a failure status of each of the storage battery and the solar power generation is acquired to determine the necessity of failure prediction.

### [Item 5]

A DC power supply system including a storage battery and a solar power generation, wherein a failure in the storage battery or the solar power generation is predicted based on data acquired from the storage battery or the solar power generation. In addition, the DC power supply system reexamines data such as the capacity or output of the storage battery and the solar power generation based on results of the failure prediction.

### [Item 6]

The DC power supply system according to item 5, wherein a failure in the storage battery is predicted by using the current capacity, current, voltage, and temperature data of the storage battery.

### [Item 7]

The DC power supply system according to item 5, wherein a failure in the solar power generation is predicted by using the output current, output voltage, and temperature data of the solar power generation.

### [Item 8]

The DC power supply system according to item 5, wherein a failure status of each of the storage battery and the solar power generation is acquired to determine the necessity of failure prediction.

### [Item 9]

The DC power supply system according to item 5, wherein a failure range is specified based on wiring information of the storage battery or the solar power generation.

The server 1 of the present disclosure has the following configuration.

[1] A failure range specifying device, including:
a storage unit that stores wiring information regarding wiring of an electrical device;
an acquisition unit that acquires failure information indicating a location in the electrical device where a failure has been predicted or determined; and
a specifying unit that specifies a failure range where the failure occurs in the electrical device based on the wiring information and the failure information.

[2] The failure range specifying device according to [1], further including:
a calculation unit that calculates an electrical capacity for a configuration of the electrical device excluding the failure range.

[3] The failure range specifying device according to [1], further including:
a configuration unit that configures the electrical device to exclude the failure range.

[4] The failure range specifying device according to [3], further including:
a calculation unit that calculates an electrical capacity for the configuration.

[5] The failure range specifying device according to any one of [1] to [4],
wherein, when the failure in the electrical device is predicted or determined, the acquisition unit acquires the failure information indicating a location in the electrical device where the failure has been predicted or determined.

[6] The failure range specifying device according to any one of [1] to [5],
wherein the electrical device is a storage battery, and
the capacity is a power storage capacity.

[7] The failure range specifying device according to any one of [1] to [5],
wherein the electrical device is a solar panel, and
the capacity is a power generation capacity.

The block diagrams used in the description of the above embodiment show blocks in functional units. These functional blocks (configuration units) are realized by any combination of at least one of hardware and software. In addition, a method of realizing each functional block is not particularly limited. That is, each functional block may be realized using one physically or logically coupled device, or may be realized by connecting two or more physically or logically separated devices directly or indirectly (for example, using a wired or wireless connection) and using the plurality of devices. Each functional block may be realized by combining the above-described one device or the above-described plurality of devices with software.

Functions include determining, judging, calculating, computing, processing, deriving, investigating, searching, ascertaining, receiving, transmitting, outputting, accessing, resolving, selecting, choosing, establishing, comparing, assuming, expecting, regarding, broadcasting, notifying, communicating, forwarding, configuring, reconfiguring, allocating, mapping, assigning, and the like, but are not limited thereto. For example, a functional block (configuration unit) that makes the transmission work is called a transmitting unit or a transmitter. In any case, as described above, the implementation method is not particularly limited.

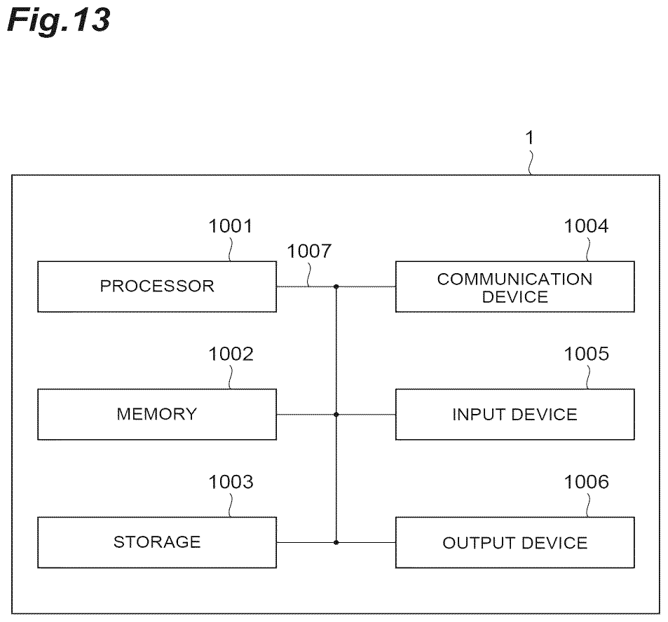

For example, the server 1 and the like according to an embodiment of the present disclosure may function as a computer that performs processing of the failure range specifying method of the present disclosure. FIG. 13 is a diagram showing an example of the hardware configuration of the server 1 according to an embodiment of the present disclosure. The server 1 described above may be physically configured as a computer device including a processor 1001, a memory 1002, a storage 1003, a communication device 1004, an input device 1005, an output device 1006, a bus 1007, and the like.

In addition, in the following description, the term “device” can be read as a circuit, a unit, and the like. The hardware configuration of the server 1 may include one or more devices for each device shown in the diagram, or may not include some devices.

Each function in the server 1 is realized by reading predetermined software (program) onto hardware, such as the processor 1001 and the memory 1002, so that the processor 1001 performs an operation and controlling communication by the communication device 1004 or controlling at least one of reading and writing of data in the memory 1002 and the storage 1003.

The processor 1001 controls the entire computer by operating an operating system, for example. The processor 1001 may be configured by a central processing unit (CPU) including an interface with a peripheral device, a control device, an operation device, a register, and the like. For example, the communication unit 11, the failure prediction unit 12, the failure determination unit 13, the failure information acquisition unit 14, the failure range specifying unit 15, the configuration unit 16, and the capacity calculation unit 17 may be realized by the processor 1001.

In addition, the processor 1001 reads a program (program code), a software module, data, and the like into the memory 1002 from at least one of the storage 1003 and the communication device 1004, and executes various kinds of processing according to these. As the program, a program causing a computer to execute at least a part of the operation described in the above embodiment is used. For example, the communication unit 11, the failure prediction unit 12, the failure determination unit 13, the failure information acquisition unit 14, the failure range specifying unit 15, the configuration unit 16 and the capacity calculation unit 17 may be realized by a control program stored in the memory 1002 and operating in the processor 1001, and the other functional blocks may be realized in a similar manner. Although it has been described that the various kinds of processes described above are performed by one processor 1001, the various kinds of processes described above may be performed simultaneously or sequentially by two or more processors 1001. The processor 1001 may be implemented by one or more chips. In addition, the program may be transmitted from a network through a telecommunication line.

The memory 1002 is a computer-readable recording medium, and may be configured by at least one of, for example, a ROM (Read Only Memory), an EPROM (Erasable Programmable ROM), an EEPROM (Electrically Erasable Programmable ROM), and a RAM (Random Access Memory). The memory 1002 may be called a register, a cache, a main memory (main storage device), and the like. The memory 1002 can store a program (program code), a software module, and the like that can be executed to implement the radio communication method according to an embodiment of the present disclosure.

The storage 1003 is a computer-readable recording medium, and may be configured by at least one of, for example, an optical disk such as a CD-ROM (Compact Disc ROM), a hard disk drive, a flexible disk, and a magneto-optical disk (for example, a compact disk, a digital versatile disk, and a Blu-ray (Registered trademark) disk), a smart card, a flash memory (for example, a card, a stick, a key drive), a floppy (registered trademark) disk, and a magnetic strip. The storage 1003 may be called an auxiliary storage device. The storage medium described above may be, for example, a database including at least one of the memory 1002 and the storage 1003, a server, or other appropriate media.

The communication device 1004 is hardware (transmitting and receiving device) for performing communication between computers through at least one of a wired network and a radio network, and is also referred to as, for example, a network device, a network controller, a network card, and a communication module. The communication device 1004 may include, for example, a high-frequency switch, a duplexer, a filter, a frequency synthesizer, and the like in order to realize at least one of frequency division duplex (FDD) and time division duplex (TDD), for example. For example, the above-described communication unit 11 and the like may be realized by the communication device 1004. The communication unit 11 may be implemented such that the transmitting unit 11a and the receiving unit 11b are physically or logically separated from each other.

The input device 1005 is an input device (for example, a keyboard, a mouse, a microphone, a switch, a button, and a sensor) for receiving an input from the outside. The output device 1006 is an output device (for example, a display, a speaker, and an LED lamp) that performs output to the outside. In addition, the input device 1005 and the output device 1006 may be integrated (for example, a touch panel).

In addition, respective devices, such as the processor 1001 and the memory 1002, are connected to each other by the bus 1007 for communicating information. The bus 1007 may be configured using a single bus, or may be configured using a different bus for each device.

In addition, the server 1 may include hardware, such as a microprocessor, a digital signal processor (DSP), an ASIC (Application Specific Integrated Circuit), a PLD (Programmable Logic Device), and an FPGA (Field Programmable Gate Array), and some or all of the functional blocks may be realized by the hardware. For example, the processor 1001 may be implemented by using at least one of these hardware components.

The notification of information is not limited to the aspects/embodiments described in the present disclosure, and may be performed using other methods.

Each aspect/embodiment described in the present disclosure may be applied to at least one of systems, which use LTE (Long Term Evolution), LTE-A (LTE-Advanced), SUPER 3G, IMT-Advanced, 4G (4th generation mobile communication system), 5G (5th generation mobile communication system), FRA (Future Radio Access), and NR (new Radio), W-CDMA (registered trademark), GSM (registered trademark), CDMA2000, UMB (Ultra Mobile Broadband), IEEE 802.11 (Wi-Fi (registered trademark)), IEEE 802.16 (WiMAX (registered trademark)), IEEE 802.20, UWB (Ultra-WideBand), Bluetooth (registered trademark), and other appropriate systems, and next-generation systems extended based on these. In addition, a plurality of systems may be combined (for example, a combination of 5G and at least one of LTE and LTE-A) to be applied.

In the processing procedure, sequence, flowchart, and the like in each aspect/embodiment described in this disclosure, the order may be changed as long as there is no contradiction. For example, for the methods described in the present disclosure, elements of various steps are presented using an exemplary order. However, the present invention is not limited to the specific order presented.

Information or the like that is input and output may be stored in a specific place (for example, a memory) or may be managed using a management table. The information or the like that is input and output can be overwritten, updated, or added. The information or the like that is output may be deleted. The information or the like that is input may be transmitted to another device.

The judging may be performed based on a value (0 or 1) expressed by 1 bit, may be performed based on the Boolean value (Boolean: true or false), or may be performed by numerical value comparison (for example, comparison with a predetermined value).

Each aspect/embodiment described in the present disclosure may be used alone, may be used in combination, or may be switched and used according to execution. In addition, the notification of predetermined information (for example, notification of “X”) is not limited to being explicitly performed, and may be performed implicitly (for example, without the notification of the predetermined information).

While the present disclosure has been described in detail, it is apparent to those skilled in the art that the present disclosure is not limited to the embodiments described in the present disclosure. The present disclosure can be implemented as modified and changed aspects without departing from the spirit and scope of the present disclosure defined by the description of the claims. Therefore, the description of the present disclosure is intended for illustrative purposes, and has no restrictive meaning to the present disclosure.

Software, regardless of whether this is called software, firmware, middleware, microcode, a hardware description language, or any other name, should be interpreted broadly to mean instructions, instruction sets, codes, code segments, program codes, programs, subprograms, software modules, applications, software applications, software packages, routines, subroutines, objects, executable files, execution threads, procedures, functions, and the like.

In addition, software, instructions, information, and the like may be transmitted and received through a transmission medium. For example, in a case where software is transmitted from a website, a server, or other remote sources using at least one of the wired technology (coaxial cable, optical fiber cable, twisted pair, digital subscriber line (DSL), and the like) and the wireless technology (infrared, microwave, and the like), at least one of the wired technology and the wireless technology is included within the definition of the transmission medium.

The information, signals, and the like described in the present disclosure may be expressed using any of a variety of different technologies. For example, data, instructions, commands, information, signals, bits, symbols, and chips that can be referred to throughout the above description may be represented by voltage, current, electromagnetic waves, magnetic field or magnetic particles, light field or photon, or any combination thereof.

In addition, the terms described in this disclosure and the terms necessary for understanding this disclosure may be replaced with terms having the same or similar meaning.

The terms “system” and “network” used in the present disclosure are used interchangeably.

In addition, the information, parameters, and the like described in the present disclosure may be expressed using an absolute value, may be expressed using a relative value from a predetermined value, or may be expressed using another corresponding information.

The names used for the parameters described above are not limiting names in any way. In addition, equations and the like using these parameters may be different from those explicitly disclosed in the present disclosure.

The term “determining” used in the present disclosure may involve a wide variety of operations. For example, “determining” can include considering judging, calculating, computing, processing, deriving, investigating, looking up (search, inquiry) (for example, looking up in a table, database, or another data structure), and ascertaining as “determining”. In addition, “determining” can include considering receiving (for example, receiving information), transmitting (for example, transmitting information), input, output, and accessing (for example, accessing data in a memory) as “determining”. In addition, “determining” can include considering resolving, selecting, choosing, establishing, comparing, and the like as “determining”. In other words, “determining” can include considering any operation as “determining”. In addition, “determining” may be read as “assuming”, “expecting”, “considering”, and the like.

The terms “connected” and “coupled” or variations thereof mean any direct or indirect connection or coupling between two or more elements, and can include a case where one or more intermediate elements are present between two elements “connected” or “coupled” to each other. The coupling or connection between elements may be physical, logical, or a combination thereof. For example, “connection” may be read as “access”. When used in the present disclosure, two elements can be considered to be “connected” or “coupled” to each other using at least one of one or more wires, cables, and printed electrical connections and using some non-limiting and non-inclusive examples, such as electromagnetic energy having wavelengths in a radio frequency domain, a microwave domain, and a light (both visible and invisible) domain.

The description “based on” used in the present disclosure does not mean “based only on” unless otherwise specified. In other words, the description “based on” means both “based only on” and “based at least on”.

Any reference to elements using designations such as “first” and “second” used in the present disclosure does not generally limit the quantity or order of the elements. These designations can be used in the present disclosure as a convenient method for distinguishing between two or more elements. Therefore, references to first and second elements do not mean that only two elements can be adopted or that the first element should precede the second element in any way.

“Means” in the configuration of each device described above may be replaced with “unit”, “circuit”, “device”, and the like.

When “include”, “including”, and variations thereof are used in the present disclosure, these terms are intended to be inclusive similarly to the term “comprising”. In addition, the term “or” used in the present disclosure is intended not to be an exclusive-OR.

In the present disclosure, in a case where articles, for example, a, an, and the in English, are added by translation, the present disclosure may include that nouns subsequent to these articles are plural.

In the present disclosure, the expression “A and B are different” may mean “A and B are different from each other”. In addition, the expression may mean that “A and B each are different from C”. Terms such as “separate” and “coupled” may be interpreted similarly to “different”.

### REFERENCE SIGNS LIST

1 . . . server, 2 . . . base station, 3 . . . power system, 10 . . . storage unit, 11 . . . communication unit, 12 . . . failure prediction unit, 13 . . . failure determination unit, 14 . . . failure information acquisition unit, 15 . . . failure range specifying unit, 16 . . . configuration unit, 17 . . . capacity calculation unit, 20 . . . storage unit, 21 . . . status acquisition unit, 22 . . . status monitoring unit, 23 . . . communication unit, 1001 . . . processor, 1002 . . . memory, 1003 . . . storage, 1004 . . . communication device, 1005 . . . input device, 1006 . . . output device, 1007 . . . bus.

1. A failure range specifying device, comprising processing circuitry configured to:
store wiring information regarding wiring of an electrical device;
acquire failure information indicating a location in the electrical device where a failure has been predicted or determined; and
specify a failure range where the failure occurs in the electrical device based on the wiring information and the failure information.

2. The failure range specifying device according to claim 1,
wherein the processing circuitry is further configured to calculate an electrical capacity for a configuration of the electrical device excluding the failure range.

3. The failure range specifying device according to claim 1,
wherein the processing circuitry is further configured to configure the electrical device to exclude the failure range.

4. The failure range specifying device according to claim 3,
wherein the processing circuitry is further configured to calculate an electrical capacity for the configuration.

5. The failure range specifying device according to claim 1,
wherein, when the failure in the electrical device is predicted or determined, the processing circuitry is configured to acquire the failure information indicating a location in the electrical device where the failure has been predicted or determined.

6. The failure range specifying device according to claim 2,
wherein the electrical device is a storage battery, and
the capacity is a power storage capacity.

7. The failure range specifying device according to claim 2,
wherein the electrical device is a solar panel, and
the capacity is a power generation capacity.

8. The failure range specifying device according to claim 2,
wherein, when the failure in the electrical device is predicted or determined, the processing circuitry is configured to acquire the failure information indicating a location in the electrical device where the failure has been predicted or determined.

9. The failure range specifying device according to claim 3,
wherein, when the failure in the electrical device is predicted or determined, the processing circuitry is configured to acquire the failure information indicating a location in the electrical device where the failure has been predicted or determined.

10. The failure range specifying device according to claim 4,
wherein, when the failure in the electrical device is predicted or determined, the processing circuitry is configured to acquire the failure information indicating a location in the electrical device where the failure has been predicted or determined.

11. The failure range specifying device according to claim 4,
wherein the electrical device is a storage battery, and
the capacity is a power storage capacity.

12. The failure range specifying device according to claim 4,
wherein the electrical device is a solar panel, and
the capacity is a power generation capacity.
